(19) United States
(12) Patent Application Publication
(10) Pub. No.: US 2012/0105385 A1
(43) Pub. Date: May 3, 2012

(54) ELECTROMECHANICAL SYSTEMS APPARATUSES AND METHODS FOR PROVIDING ROUGH SURFACES

(75) Inventors: Teruo Sasagawa, Los Gatos, CA (US); Leonard Eugene Fennell, Foster City, CA (US)

(73) Assignee: QUALCOMM MEMS Technologies, Inc., San Diego, CA (US)

(21) Appl. No.: 12/917,759

(22) Filed: Nov. 2, 2010

(51) Int. Cl. G09G 5/00; H01L 29/84; H01L 21/02; B82Y 30/00

(52) U.S. Cl. 345/204; 438/50; 257/415; 257/E21.002; 257/E29.324; 977/773

(57) ABSTRACT

This disclosure provides systems, methods, and apparatus for producing roughness in an electromechanical device by nucleation under plasma CVD conditions. In one aspect, a substrate and at least a first layer are provided. The disclosure further provides gas phase nucleating particles under plasma CVD conditions and depositing a first layer, where the particles are incorporated into the first layer to create roughness in the first layer. The roughness may be transferred to a second layer by conformal deposition of the second layer over the first layer. The roughness of the second layer corresponds to the roughness of the first layer, where the first layer has a roughness greater than or equal to about 20 Å root mean square (RMS).

### TECHNICAL FIELD

This disclosure relates to electromechanical systems apparatuses and methods of making the same. More particularly, this disclosure relates to engineering surfaces for improving performance of electromechanical systems.

### DESCRIPTION OF THE RELATED TECHNOLOGY

Electromechanical systems include apparatuses having electrical and mechanical elements, actuators, transducers, sensors, optical components (e.g., mirrors) and electronics. Electromechanical systems can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, and/or other micromachining processes that etch away parts of substrates and/or deposited material layers, or that add layers to form electrical and electromechanical devices.

One type of electromechanical systems apparatus is called an interferometric modulator (IMOD). As used herein, the term interferometric modulator or interferometric light modulator refers to a device that selectively absorbs and/or reflects light using the principles of optical interference. In some implementations, an interferometric modulator may include a pair of conductive plates, one or both of which may be transparent and/or reflective, wholly or in part, and capable of relative motion upon application of an appropriate electrical signal. In an implementation, one plate may include a stationary layer deposited on a substrate and the other plate may include a reflective membrane separated from the stationary layer by an air gap. The position of one plate in relation to another can change the optical interference of light incident on the interferometric modulator. Interferometric modulator devices have a wide range of applications, and are anticipated to be used in improving existing products and creating new products, especially those with display capabilities.

### SUMMARY

The systems, methods and devices of the disclosure each have several innovative aspects, no single one of which is solely responsible for the desirable attributes disclosed herein.

One innovative aspect of the subject matter described in this disclosure can be implemented in a method of producing roughness in an electromechanical apparatus. The method includes providing a substrate, gas phase nucleating particles under plasma chemical vapor deposition (CVD) conditions, and depositing a first layer including the particles to create roughness in the first layer of the electromechanical apparatus. The roughness of the first layer can be greater than or equal to about 20 Å root mean square (RMS).

The method can further include forming a third layer over the second layer, the second and third layers defining a gap therebetween, the third layer having at least open and closed states for the electromechanical apparatus. The third layer can form part of a movable electrode and the second layer can form part of a stationary electrode. In some implementations, the gas phase nucleating particles can be performed concurrently with depositing the first layer.

In accordance with another implementation, an electromechanical systems apparatus is provided. The apparatus includes a substrate, a first layer, and a plurality of particles embedded in the first layer to create roughness in the first layer. The particles can be substantially homogeneous in composition with the remainder of the first layer. The roughness of the first layer can greater than or equal to about 20 Å RMS.

The electromechanical systems apparatus can further include additional particles on top of the first layer.

In accordance with another implementation, an electromechanical systems apparatus is provided. The apparatus includes a substrate, a buffer layer formed on the substrate where the buffer layer has a roughened surface, a stationary electrode formed over the buffer layer where the stationary electrode has a rough surface corresponding to the roughened surface of the buffer layer, a movable electrode, and a gap defined between the movable electrode and the stationary electrode. The movable electrode can be configured to move across the gap to define at least an acutated and unactuated state.

The surface of the movable electrode of the electromechanical systems apparatus can have a rough surface corresponding to the rough surface of the stationary electrode. Additionally, the buffer player of the electromechanical systems apparatus can include a plurality of particles. The particles can include material that is substantially homogeneous in composition with the remainder of the buffer layer.

In accordance with another implementation, a method of manufacturing an electromechanical systems apparatus is provided. The method includes providing a substrate, forming a buffer layer with a roughened surface over the substrate, depositing a stationary electrode conformally over the buffer layer, and forming a movable electrode over the stationary layer. The movable electrode and the stationary electrode define a gap therebetween, where the movable electrode has at least actuated and unactuated states.

Depositing the stationary electrode can include transferring roughness of the roughened surface to the stationary electrode by conformal deposition of the stationary layer over the buffer layer. In addition, the method can further include depositing a sacrificial layer over the stationary electrode, where forming the movable electrode can include depositing the movable over the sacrificial layer. The method can further include removing the sacrificial layer by applying an etchant.

In accordance with another implementation, an electromechanical systems apparatus is provided. The apparatus includes means for supporting the electromechanical systems apparatus and first means for conducting electricity where the first means for conducting can be positioned over the means for supporting. The apparatus further includes means for roughening the first means for conducting where the means for roughening can be positioned between the means for supporting and the first means for conducting. The apparatus further includes second means for conducting electricity where the second means for conducting electricity can be configured to move between an open state and a closed state in response to electrostatic forces between the first and the second means for conducting.

The means for roughening in the electromechanical systems apparatus can have a roughness greater than or equal to about 20 Å root mean square (RMS). In addition, the means for roughening can include a plurality of particles having an average diameter between about 15 Å and about 50 Å.

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE FIGURES

FIG. 1 shows an example of an isometric view depicting two adjacent pixels in a series of pixels of an interferometric modulator (IMOD) display device.

FIG. 2 shows an example of a system block diagram illustrating an electronic device incorporating a 3×3 interferometric modulator display.

FIG. 3A shows an example of a diagram illustrating movable reflective layer position versus applied voltage for the interferometric modulator of FIG. 1.

FIG. 3B shows an example of a table illustrating various states of an interferometric modulator when various common and segment voltages are applied.

FIG. 4A shows an example of a diagram illustrating a frame of display data in the 3×3 interferometric modulator display of FIG. 2.

FIG. 4B shows an example of a timing diagram for common and segment signals that may be used to write the frame of display data illustrated in FIG. 4A.

FIG. 5A shows an example of a partial cross-section of the interferometric modulator display of FIG. 1.

FIGS. 5B-5E show examples of cross-sections of varying implementations of interferometric modulators.

FIG. 6 shows an example of a flow diagram illustrating a manufacturing process for an interferometric modulator.

FIGS. 7A-7E show examples of cross-sectional schematic illustrations of various stages in a method of making an interferometric modulator.

FIG. 8A shows an example of a flow diagram illustrating a method of making an electromechanical systems apparatus in accordance with one implementation.

FIG. 8B shows an example of a flow diagram illustrating a method of making an electromechanical systems apparatus in accordance with another implementation.

FIG. 9A shows an example of a flow diagram illustrating a method of making an electromechanical systems apparatus in accordance with another implementation.

FIG. 9B shows an example of a flow diagram illustrating a method of making an electromechanical systems apparatus in accordance with still another implementation.

FIGS. 10A through 10E show examples of cross-sections illustrating processing for manufacturing an electromechanical systems apparatus.

FIGS. 11A and 11B show examples of system block diagrams illustrating a display device that includes a plurality of interferometric modulators.

Like reference numbers and designations in the various drawings indicate like elements.

### DETAILED DESCRIPTION

The following detailed description is directed to certain implementations for the purposes of describing the innovative aspects. However, the teachings herein can be applied in a multitude of different ways. The described implementations may be implemented in any device that is configured to display an image, whether in motion (e.g., video) or stationary (e.g., still image), and whether textual, graphical or pictorial. More particularly, it is contemplated that the implementations may be implemented in or associated with a variety of electronic devices such as, but not limited to, mobile telephones, multimedia Internet enabled cellular telephones, mobile television receivers, wireless devices, smartphones, bluetooth devices, personal data assistants (PDAs), wireless electronic mail receivers, hand-held or portable computers, netbooks, notebooks, smartbooks, printers, copiers, scanners, facsimile devices, GPS receivers/navigators, cameras, MP3 players, camcorders, game consoles, wrist watches, clocks, calculators, television monitors, flat panel displays, electronic reading devices (e.g., e-readers), computer monitors, auto displays (e.g., odometer display, etc.), cockpit controls and/or displays, camera view displays (e.g., display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, packaging (e.g., MEMS and non-MEMS), aesthetic structures (e.g., display of images on a piece of jewelry) and a variety of electromechanical systems devices. The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes, electronic test equipment. Thus, the teachings are not intended to be limited to the implementations depicted solely in the Figures, but instead have wide applicability as will be readily apparent to one having ordinary skill in the art.

In certain implementations, methods of producing roughness in electromechanical systems device are provided. The methods include providing a substrate and gas phase nucleating particles under plasma chemical vapor deposition (CVD) conditions. A first layer is deposited including the nucleated particles to create roughness in the first layer. The methods may further include transferring roughness to a second layer by conformal deposition of a second layer over the first layer. Particular implementations of the subject matter described in this disclosure can be implemented to realize one or more potential advantages. One potential advantage of producing roughness in such a manner is to reduce the effects of stiction in between a movable layer and a stationary layer of the electromechanical systems device. In a more specific implementation, the first layer may be a buffer layer between a transparent substrate and optical layer(s) of an optical electromechanical systems device. Roughness from particles can thus be transferred to overlying optical layer(s) without interfering with the optics.

One example of a suitable MEMS device, to which the described implementations may apply, is a reflective display device. Reflective display devices can incorporate interferometric modulators (IMODs) to selectively absorb and/or reflect light incident thereon using principles of optical interference. IMODs can include an absorber, a reflector that is movable with respect to the absorber, and an optical resonant cavity defined between the absorber and the reflector. The reflector can be moved to two or more different positions, which can change the size of the optical resonant cavity and thereby affect the reflectance of the interferometric modulator. The reflectance spectrums of IMODs can create fairly broad spectral bands which can be shifted across the visible wavelengths to generate different colors. The position of the spectral band can be adjusted by changing the thickness of the optical resonant cavity, i.e., by changing the position of the reflector.

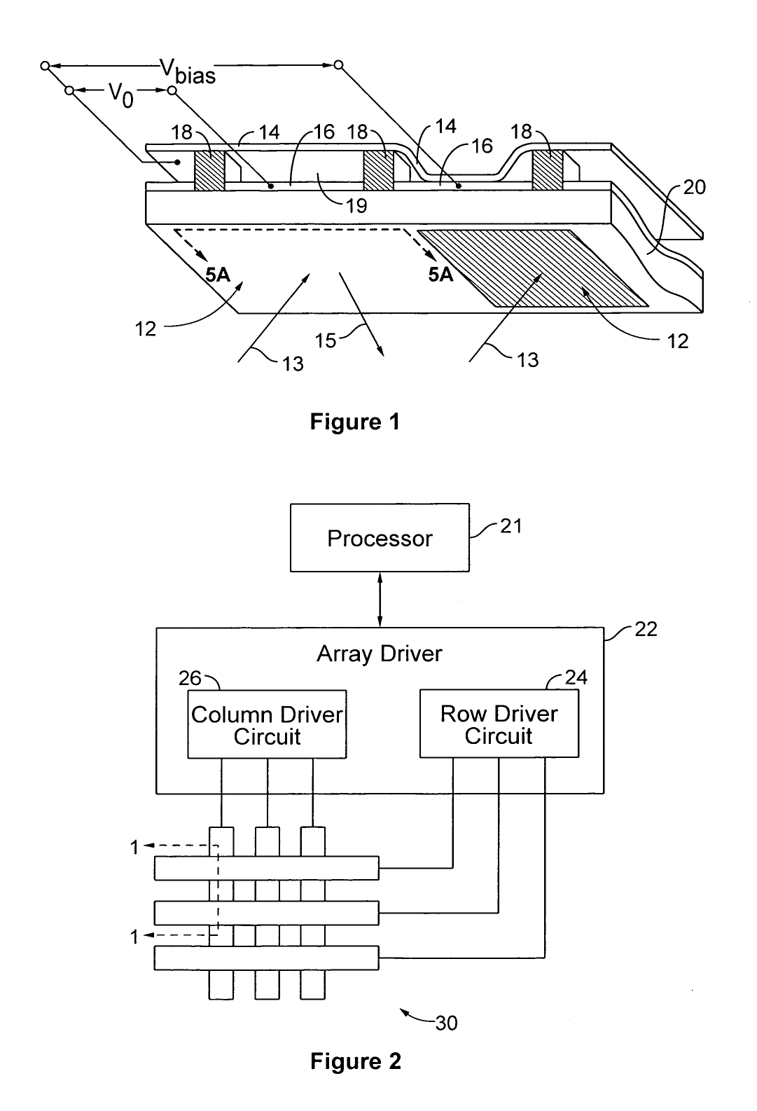

FIG. 1 shows an example of an isometric view depicting two adjacent pixels in a series of pixels of an interferometric modulator (IMOD) display device. The IMOD display device includes one or more interferometric MEMS display elements. In these devices, the pixels of the MEMS display elements can be in either a bright or dark state. In the bright (“relaxed,” “open” or “on”) state, the display element reflects a large portion of incident visible light, e.g., to a user. Conversely, in the dark (“actuated,” “closed” or “off”) state, the display element reflects little incident visible light. In some implementations, the light reflectance properties of the on and off states may be reversed. MEMS pixels can be configured to reflect predominantly at particular wavelengths allowing for a color display in addition to black and white.

The IMOD display device can include a row/column array of IMODs. Each IMOD can include a pair of reflective layers, i.e., a movable reflective layer and a fixed partially reflective layer, positioned at a variable and controllable distance from each other to form an air gap (also referred to as an optical gap or cavity). The movable reflective layer may be moved between at least two positions. In a first position, i.e., a relaxed position, the movable reflective layer can be positioned at a relatively large distance from the fixed partially reflective layer. In a second position, i.e., an actuated position, the movable reflective layer can be positioned more closely to the partially reflective layer. Incident light that reflects from the two layers can interfere constructively or destructively depending on the position of the movable reflective layer, producing either an overall reflective or non-reflective state for each pixel. In some implementations, the IMOD may be in a reflective state when unactuated, reflecting light within the visible spectrum, and may be in a dark state when unactuated, reflecting light outside of the visible range (e.g., infrared light). In some other implementations, however, an IMOD may be in a dark state when unactuated, and in a reflective state when actuated. In some implementations, the introduction of an applied voltage can drive the pixels to change states. In some other implementations, an applied charge can drive the pixels to change states.

The depicted portion of the pixel array in FIG. 1 includes two adjacent interferometric modulators 12. In the IMOD 12 on the left (as illustrated), a movable reflective layer 14 is illustrated in a relaxed position at a predetermined distance from an optical stack 16, which includes a partially reflective layer. The voltage V₀ applied across the IMOD 12 on the left is insufficient to cause actuation of the movable reflective layer 14. In the IMOD 12 on the right, the movable reflective layer 14 is illustrated in an actuated position near or adjacent the optical stack 16. The voltage V_{bias} applied across the IMOD 12 on the right is sufficient to maintain the movable reflective layer 14 in the actuated position.

In FIG. 1, the reflective properties of pixels 12 are generally illustrated with arrows 13 indicating light incident upon the pixels 12, and light 15 reflecting from the pixel 12 on the left. Although not illustrated in detail, it will be understood by one having ordinary skill in the art that most of the light 13 incident upon the pixels 12 will be transmitted through the transparent substrate 20, toward the optical stack 16. A portion of the light incident upon the optical stack 16 will be transmitted through the partially reflective layer of the optical stack 16, and a portion will be reflected back through the transparent substrate 20. The portion of light 13 that is transmitted through the optical stack 16 will be reflected at the movable reflective layer 14, back toward (and through) the transparent substrate 20. Interference (constructive or destructive) between the light reflected from the partially reflective layer of the optical stack 16 and the light reflected from the movable reflective layer 14 will determine the wavelength(s) of light 15 reflected from the pixel 12.

The optical stack 16 can include a single layer or several layers. The layer(s) can include one or more of an electrode layer, a partially reflective and partially transmissive layer and a transparent dielectric layer. In some implementations, the optical stack 16 is electrically conductive, partially transparent and partially reflective, and may be fabricated, for example, by depositing one or more of the above layers onto a transparent substrate 20. The electrode layer can be formed from a variety of materials, such as various metals, for example indium tin oxide (ITO). The partially reflective layer can be formed from a variety of materials that are partially reflective, such as various metals, e.g., chromium (Cr), semiconductors, and dielectrics. The partially reflective layer can be formed of one or more layers of materials, and each of the layers can be formed of a single material or a combination of materials. In some implementations, the optical stack 16 can include a single semi-transparent thickness of metal or semiconductor which serves as both an optical absorber and conductor, while different, more conductive layers or portions (e.g., of the optical stack 16 or of other structures of the IMOD) can serve to bus signals between IMOD pixels. The optical stack 16 also can include one or more insulating or dielectric layers covering one or more conductive layers or a conductive/absorptive layer.

In some implementations, the layer(s) of the optical stack 16 can be patterned into parallel strips, and may form row electrodes in a display device as described further below. As will be understood by one having skill in the art, the term “patterned” is used herein to refer to masking as well as etching processes. In some implementations, a highly conductive and reflective material, such as aluminum (Al), may be used for the movable reflective layer 14, and these strips may form column electrodes in a display device. The movable reflective layer 14 may be formed as a series of parallel strips of a deposited metal layer or layers (orthogonal to the row electrodes of the optical stack 16) to form columns deposited on top of posts 18 and an intervening sacrificial material deposited between the posts 18. When the sacrificial material is etched away, a defined gap 19, or optical cavity, can be formed between the movable reflective layer 14 and the optical stack 16. In some implementations, the spacing between posts 18 may be on the order of 1-1000 um, while the gap 19 may be on the order of <10,000 Angstroms (Å).

In some implementations, each pixel of the IMOD, whether in the actuated or relaxed state, is essentially a capacitor formed by the fixed and moving reflective layers. When no voltage is applied, the movable reflective layer 14a remains in a mechanically relaxed state, as illustrated by the pixel 12 on the left in FIG. 1, with the gap 19 between the movable reflective layer 14 and optical stack 16. However, when a potential difference, e.g., voltage, is applied to at least one of a selected row and column, the capacitor formed at the intersection of the row and column electrodes at the corresponding pixel becomes charged, and electrostatic forces pull the electrodes together. If the applied voltage exceeds a threshold, the movable reflective layer 14 can deform and move near or against the optical stack 16. A dielectric layer (not shown) within the optical stack 16 may prevent shorting and control the separation distance between the layers 14 and 16, as illustrated by the actuated pixel 12 on the right in FIG. 1. The behavior is the same regardless of the polarity of the applied potential difference. Though a series of pixels in an array may be referred to in some instances as “rows” or “columns,” a person having ordinary skill in the art will readily understand that referring to one direction as a “row” and another as a “column” is arbitrary. Restated, in some orientations, the rows can be considered columns, and the columns considered to be rows. Furthermore, the display elements may be evenly arranged in orthogonal rows and columns (an “array”), or arranged in non-linear configurations, for example, having certain positional offsets with respect to one another (a “mosaic”). The terms “array” and “mosaic” may refer to either configuration. Thus, although the display is referred to as including an “array” or “mosaic,” the elements themselves need not be arranged orthogonally to one another, or disposed in an even distribution, in any instance, but may include arrangements having asymmetric shapes and unevenly distributed elements.

FIG. 2 shows an example of a system block diagram illustrating an electronic device incorporating a 3×3 interferometric modulator display. The electronic device includes a processor 21 that may be configured to execute one or more software modules. In addition to executing an operating system, the processor 21 may be configured to execute one or more software applications, including a web browser, a telephone application, an email program, or any other software application.

The processor 21 can be configured to communicate with an array driver 22. The array driver 22 can include a row driver circuit 24 and a column driver circuit 26 that provide signals to, e.g., a display array or panel 30. The cross section of the IMOD display device illustrated in FIG. 1 is shown by the lines 1-1 in FIG. 2. Although FIG. 2 illustrates a 3×3 array of IMODs for the sake of clarity, the display array 30 may contain a very large number of IMODs, and may have a different number of IMODs in rows than in columns, and vice versa.

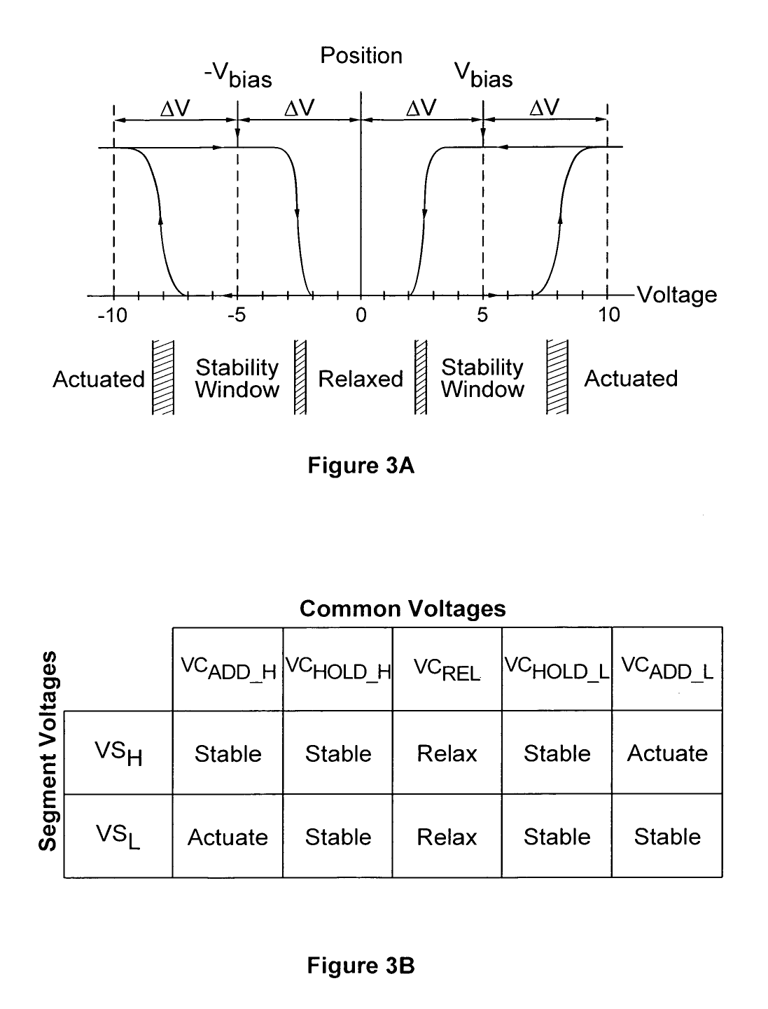

FIG. 3A shows an example of a diagram illustrating movable reflective layer position versus applied voltage for the interferometric modulator of FIG. 1. For MEMS interferometric modulators, the row/column (i.e., common/segment) write procedure may take advantage of a hysteresis property of these devices as illustrated in FIG. 3A. An interferometric modulator may require, for example, about a 10-volt potential difference to cause the movable reflective layer, or mirror, to change from the relaxed state to the actuated state. When the voltage is reduced from that value, the movable reflective layer maintains its state as the voltage drops back below, e.g., 10-volts, however, the movable reflective layer does not relax completely until the voltage drops below 2-volts. Thus, a range of voltage, approximately 3 to 7-volts, as shown in FIG. 3A, exists where there is a window of applied voltage within which the device is stable in either the relaxed or actuated state. This is referred to herein as the “hysteresis window” or “stability window.” For a display array 30 having the hysteresis characteristics of FIG. 3A, the row/column write procedure can be designed to address one or more rows at a time, such that during the addressing of a given row, pixels in the addressed row that are to be actuated are exposed to a voltage difference of about 10-volts, and pixels that are to be relaxed are exposed to a voltage difference of near zero volts. After addressing, the pixels are exposed to a steady state or bias voltage difference of approximately 5-volts such that they remain in the previous strobing state. In this example, after being addressed, each pixel sees a potential difference within the “stability window” of about 3-7-volts. This hysteresis property feature enables the pixel design, e.g., illustrated in FIG. 1, to remain stable in either an actuated or relaxed pre-existing state under the same applied voltage conditions. Since each IMOD pixel, whether in the actuated or relaxed state, is essentially a capacitor formed by the fixed and moving reflective layers, this stable state can be held at a steady voltage within the hysteresis window without substantially consuming or losing power. Moreover, essentially little or no current flows into the IMOD pixel if the applied voltage potential remains substantially fixed.

In some implementations, a frame of an image may be created by applying data signals in the form of “segment” voltages along the set of column electrodes, in accordance with the desired change (if any) to the state of the pixels in a given row. Each row of the array can be addressed in turn, such that the frame is written one row at a time. To write the desired data to the pixels in a first row, segment voltages corresponding to the desired state of the pixels in the first row can be applied on the column electrodes, and a first row pulse in the form of a specific “common” voltage or signal can be applied to the first row electrode. The set of segment voltages can then be changed to correspond to the desired change (if any) to the state of the pixels in the second row, and a second common voltage can be applied to the second row electrode. In some implementations, the pixels in the first row are unaffected by the change in the segment voltages applied along the column electrodes, and remain in the state they were set to during the first common voltage row pulse. This process may be repeated for the entire series of rows, or alternatively, columns, in a sequential fashion to produce the image frame. The frames can be refreshed and/or updated with new image data by continually repeating this process at some desired number of frames per second.

The combination of segment and common signals applied across each pixel (that is, the potential difference across each pixel) determines the resulting state of each pixel. FIG. 3B shows an example of a table illustrating various states of an interferometric modulator when various common and segment voltages are applied. As will be readily understood by one having ordinary skill in the art, the “segment” voltages can be applied to either the column electrodes or the row electrodes, and the “common” voltages can be applied to the other of the column electrodes or the row electrodes.

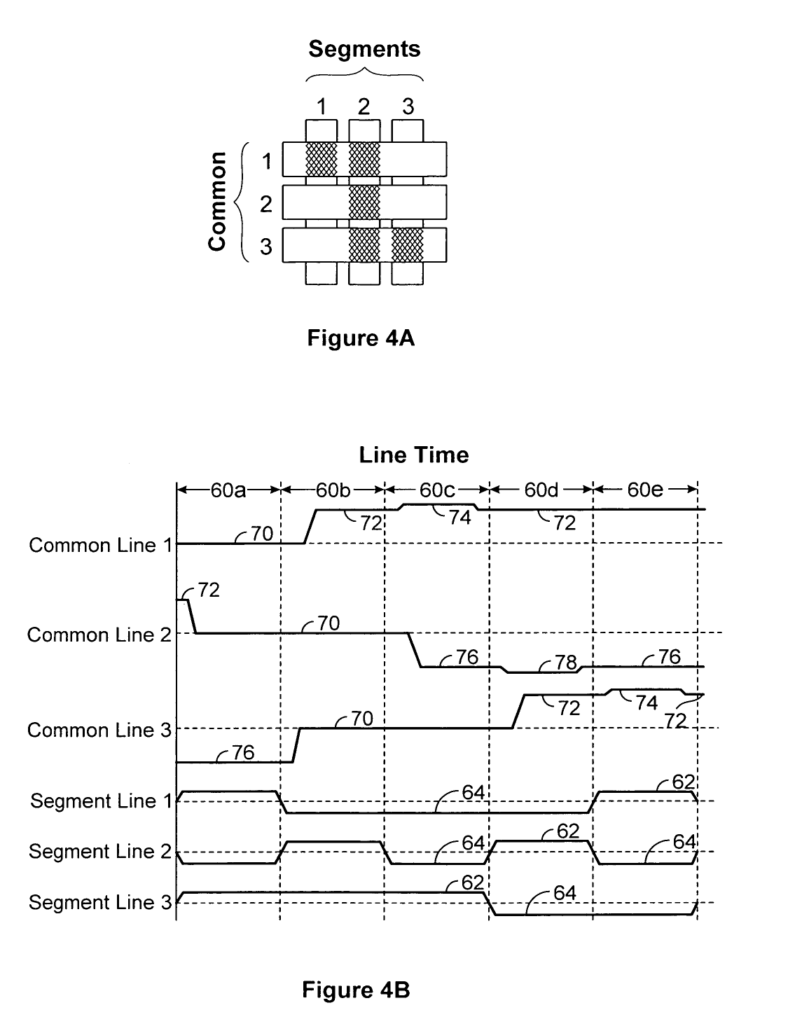

As illustrated in FIG. 3B (as well as in the timing diagram shown in FIG. 4B), when a release voltage VC_{REL} is applied along a common line, all interferometric modulator elements along the common line will be placed in a relaxed state, alternatively referred to as a released or unactuated state, regardless of the voltage applied along the segment lines, i.e., high segment voltage VS_{H} and low segment voltage VS_{L}. In particular, when the release voltage VC_{REL} is applied along a common line, the potential voltage across the modulator (alternatively referred to as a pixel voltage) is within the relaxation window (see FIG. 3A, also referred to as a release window) both when the high segment voltage VS_{H} and the low segment voltage VS_{L} are applied along the corresponding segment line for that pixel.

When a hold voltage is applied on a common line, such as a high hold voltage VC_{HOLD}_{_{—}}_{H} or a low hold voltage VC_{HOLD}_{_{—}}_{L}, the state of the interferometric modulator will remain constant. For example, a relaxed IMOD will remain in a relaxed position, and an actuated IMOD will remain in an actuated position. The hold voltages can be selected such that the pixel voltage will remain within a stability window both when the high segment voltage VS_{H} and the low segment voltage VS_{L} are applied along the corresponding segment line. Thus, the segment voltage swing, i.e., the difference between the high VS_{H} and low segment voltage VS_{L}, is less than the width of either the positive or the negative stability window.

When an addressing, or actuation, voltage is applied on a common line, such as a high addressing voltage VC_{ADD}_{_{—}}_{H} or a low addressing voltage VC_{ADD}_{_{—}}_{L}, data can be selectively written to the modulators along that line by application of segment voltages along the respective segment lines. The segment voltages may be selected such that actuation is dependent upon the segment voltage applied. When an addressing voltage is applied along a common line, application of one segment voltage will result in a pixel voltage within a stability window, causing the pixel to remain unactuated. In contrast, application of the other segment voltage will result in a pixel voltage beyond the stability window, resulting in actuation of the pixel. The particular segment voltage which causes actuation can vary depending upon which addressing voltage is used. In some implementations, when the high addressing voltage VC_{ADD}_{_{—}}_{H} is applied along the common line, application of the high segment voltage VS_{H} can cause a modulator to remain in its current position, while application of the low segment voltage VS_{L} can cause actuation of the modulator. As a corollary, the effect of the segment voltages can be the opposite when a low addressing voltage VC_{ADD}_{_{—}}_{L} is applied, with high segment voltage VS_{H} causing actuation of the modulator, and low segment voltage VS_{L} having no effect (i.e., remaining stable) on the state of the modulator.

In some implementations, hold voltages, address voltages, and segment voltages may be used which always produce the same polarity potential difference across the modulators. In some other implementations, signals can be used which alternate the polarity of the potential difference of the modulators. Alternation of the polarity across the modulators (that is, alternation of the polarity of write procedures) may reduce or inhibit charge accumulation which could occur after repeated write operations of a single polarity.

FIG. 4A shows an example of a diagram illustrating a frame of display data in the 3×3 interferometric modulator display of FIG. 2. FIG. 4B shows an example of a timing diagram for common and segment signals that may be used to write the frame of display data illustrated in FIG. 4A. The signals can be applied to the, e.g., 3×3 array of FIG. 2, which will ultimately result in the line time 60e display arrangement illustrated in FIG. 4A. The actuated modulators in FIG. 4A are in a dark-state, i.e., where a substantial portion of the reflected light is outside of the visible spectrum so as to result in a dark appearance to, e.g., a viewer. Prior to writing the frame illustrated in FIG. 4A, the pixels can be in any state, but the write procedure illustrated in the timing diagram of FIG. 4B presumes that each modulator has been released and resides in an unactuated state before the first line time 60a.

During the first line time 60a: a release voltage 70 is applied on common line 1; the voltage applied on common line 2 begins at a high hold voltage 72 and moves to a release voltage 70; and a low hold voltage 76 is applied along common line 3. Thus, the modulators (common 1, segment 1), (1,2) and (1,3) along common line 1 remain in a relaxed, or unactuated, state for the duration of the first line time 60a, the modulators (2,1), (2,2) and (2,3) along common line 2 will move to a relaxed state, and the modulators (3,1), (3,2) and (3,3) along common line 3 will remain in their previous state. With reference to FIG. 3B, the segment voltages applied along segment lines 1, 2 and 3 will have no effect on the state of the interferometric modulators, as none of common lines 1, 2 or 3 are being exposed to voltage levels causing actuation during line time 60a (i.e., VC_{REL}—relax and VC_{HOLD}_{_{—}}_{L}—stable).

During the second line time 60b, the voltage on common line 1 moves to a high hold voltage 72, and all modulators along common line 1 remain in a relaxed state regardless of the segment voltage applied because no addressing, or actuation, voltage was applied on the common line 1. The modulators along common line 2 remain in a relaxed state due to the application of the release voltage 70, and the modulators (3,1), (3,2) and (3,3) along common line 3 will relax when the voltage along common line 3 moves to a release voltage 70.

During the third line time 60c, common line 1 is addressed by applying a high address voltage 74 on common line 1. Because a low segment voltage 64 is applied along segment lines 1 and 2 during the application of this address voltage, the pixel voltage across modulators (1,1) and (1,2) is greater than the high end of the positive stability window (i.e., the voltage differential exceeded a predefined threshold) of the modulators, and the modulators (1,1) and (1,2) are actuated. Conversely, because a high segment voltage 62 is applied along segment line 3, the pixel voltage across modulator (1,3) is less than that of modulators (1,1) and (1,2), and remains within the positive stability window of the modulator; modulator (1,3) thus remains relaxed. Also during line time 60c, the voltage along common line 2 decreases to a low hold voltage 76, and the voltage along common line 3 remains at a release voltage 70, leaving the modulators along common lines 2 and 3 in a relaxed position.

During the fourth line time 60d, the voltage on common line 1 returns to a high hold voltage 72, leaving the modulators along common line 1 in their respective addressed states. The voltage on common line 2 is decreased to a low address voltage 78. Because a high segment voltage 62 is applied along segment line 2, the pixel voltage across modulator (2,2) is below the lower end of the negative stability window of the modulator, causing the modulator (2,2) to actuate. Conversely, because a low segment voltage 64 is applied along segment lines 1 and 3, the modulators (2,1) and (2,3) remain in a relaxed position. The voltage on common line 3 increases to a high hold voltage 72, leaving the modulators along common line 3 in a relaxed state.

Finally, during the fifth line time 60e, the voltage on common line 1 remains at high hold voltage 72, and the voltage on common line 2 remains at a low hold voltage 76, leaving the modulators along common lines 1 and 2 in their respective addressed states. The voltage on common line 3 increases to a high address voltage 74 to address the modulators along common line 3. As a low segment voltage 64 is applied on segment lines 2 and 3, the modulators (3,2) and (3,3) actuate, while the high segment voltage 62 applied along segment line 1 causes modulator (3,1) to remain in a relaxed position. Thus, at the end of the fifth line time 60e, the 3×3 pixel array is in the state shown in FIG. 4A, and will remain in that state as long as the hold voltages are applied along the common lines, regardless of variations in the segment voltage which may occur when modulators along other common lines (not shown) are being addressed.

In the timing diagram of FIG. 4B, a given write procedure (i.e., line times 60a-60e) can include the use of either high hold and address voltages, or low hold and address voltages. Once the write procedure has been completed for a given common line (and the common voltage is set to the hold voltage having the same polarity as the actuation voltage), the pixel voltage remains within a given stability window, and does not pass through the relaxation window until a release voltage is applied on that common line. Furthermore, as each modulator is released as part of the write procedure prior to addressing the modulator, the actuation time of a modulator, rather than the release time, may determine the necessary line time. Specifically, in implementations in which the release time of a modulator is greater than the actuation time, the release voltage may be applied for longer than a single line time, as depicted in FIG. 4B. In some other implementations, voltages applied along common lines or segment lines may vary to account for variations in the actuation and release voltages of different modulators, such as modulators of different colors.

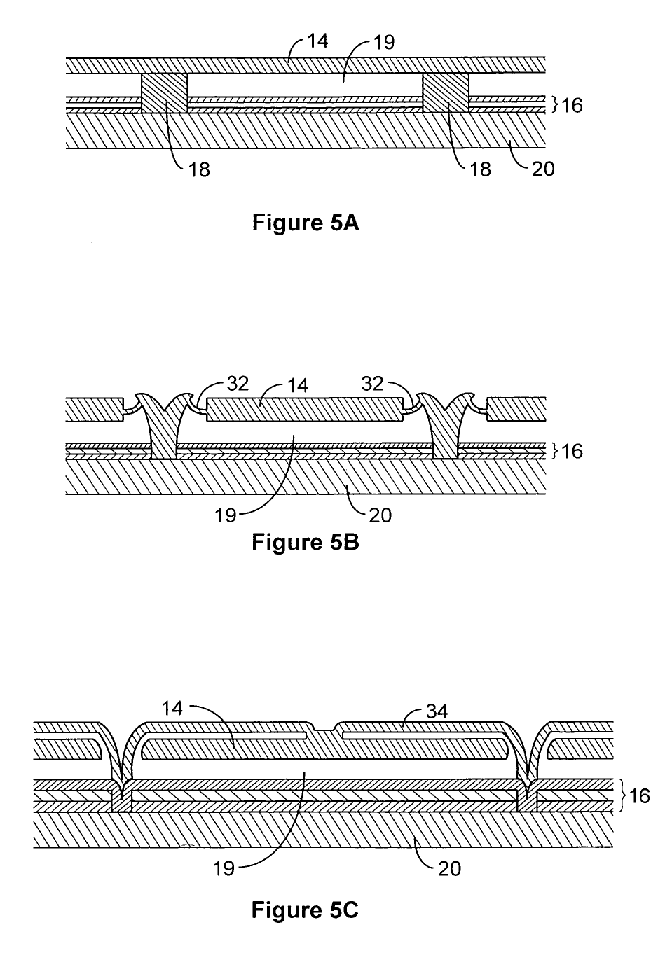

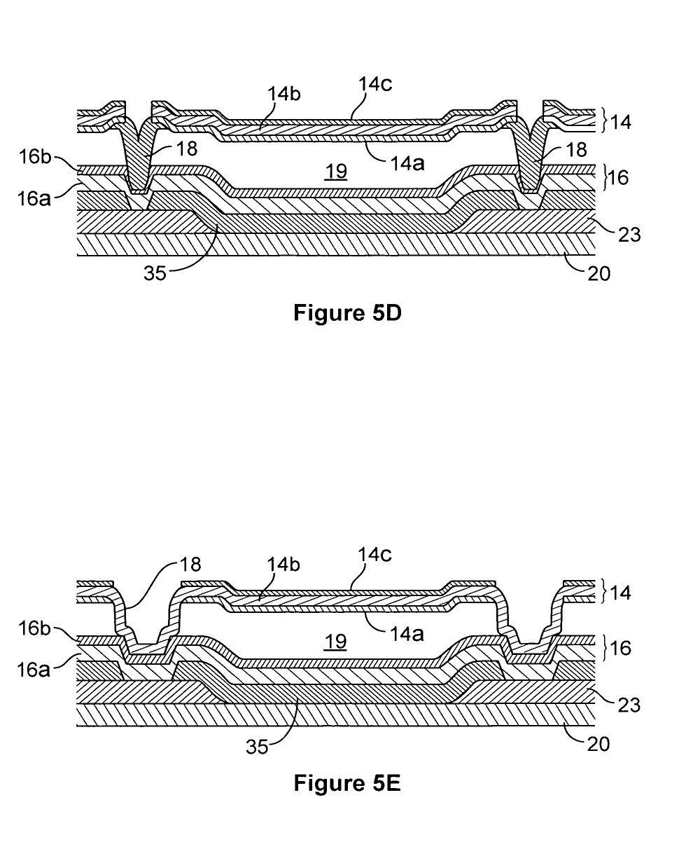

The details of the structure of interferometric modulators that operate in accordance with the principles set forth above may vary widely. For example, FIGS. 5A-5E show examples of cross-sections of varying implementations of interferometric modulators, including the movable reflective layer 14 and its supporting structures. FIG. 5A shows an example of a partial cross-section of the interferometric modulator display of FIG. 1, where a strip of metal material, i.e., the movable reflective layer 14 is deposited on supports 18 extending orthogonally from the substrate 20. In FIG. 5B, the movable reflective layer 14 of each IMOD is generally square or rectangular in shape and attached to supports at or near the corners, on tethers 32. In FIG. 5C, the movable reflective layer 14 is generally square or rectangular in shape and suspended from a deformable layer 34, which may include a flexible metal. The deformable layer 34 can connect, directly or indirectly, to the substrate 20 around the perimeter of the movable reflective layer 14. These connections are herein referred to as support posts. The implementation shown in FIG. 5C has additional benefits deriving from the decoupling of the optical functions of the movable reflective layer 14 from its mechanical functions, which are carried out by the deformable layer 34. This decoupling allows the structural design and materials used for the reflective layer 14 and those used for the deformable layer 34 to be optimized independently of one another.

FIG. 5D shows another example of an IMOD, where the movable reflective layer 14 includes a reflective sub-layer 14a. The movable reflective layer 14 rests on a support structure, such as support posts 18. The support posts 18 provide separation of the movable reflective layer 14 from the lower stationary electrode (i.e., part of the optical stack 16 in the illustrated IMOD) so that a gap 19 is formed between the movable reflective layer 14 and the optical stack 16, for example when the movable reflective layer 14 is in a relaxed position. The movable reflective layer 14 also can include a conductive layer 14c, which may be configured to serve as an electrode, and a support layer 14b. In this example, the conductive layer 14c is disposed on one side of the support layer 14b, distal from the substrate 20, and the reflective sub-layer 14a is disposed on the other side of the support layer 14b, proximal to the substrate 20. In some implementations, the reflective sub-layer 14a can be conductive and can be disposed between the support layer 14b and the optical stack 16. The support layer 14b can include one or more layers of a dielectric material, for example, silicon oxynitride (SiON) or silicon dioxide (SiO₂). In some implementations, the support layer 14b can be a stack of layers, such as, for example, a SiO₂/SiON/SiO₂ tri-layer stack. Either or both of the reflective sub-layer 14a and the conductive layer 14c can include, e.g., an Al alloy with about 0.5% Cu, or another reflective metallic material. Employing conductive layers 14a, 14c above and below the dielectric support layer 14b can balance stresses and provide enhanced conduction. In some implementations, the reflective sub-layer 14a and the conductive layer 14c can be formed of different materials for a variety of design purposes, such as achieving specific stress profiles within the movable reflective layer 14.

As illustrated in FIG. 5D, some implementations also can include a black mask structure 23. The black mask structure 23 can be formed in optically inactive regions (e.g., between pixels or under posts 18) to absorb ambient or stray light. The black mask structure 23 also can improve the optical properties of a display device by inhibiting light from being reflected from or transmitted through inactive portions of the display, thereby increasing the contrast ratio. Additionally, the black mask structure 23 can be conductive and be configured to function as an electrical bussing layer. In some implementations, the row electrodes can be connected to the black mask structure 23 to reduce the resistance of the connected row electrode. The black mask structure 23 can be formed using a variety of methods, including deposition and patterning techniques. The black mask structure 23 can include one or more layers. For example, in some implementations, the black mask structure 23 includes a molybdenum-chromium (MoCr) layer that serves as an optical absorber, a SiO₂ layer, and an aluminum alloy that serves as a reflector and a bussing layer, with a thickness in the range of about 30-80 Å, 500-1000 Å, and 500-6000 Å, respectively. The one or more layers can be patterned using a variety of techniques, including photolithography and dry etching, including, for example, CF₄ and/or O₂ for the MoCr and SiO₂ layers and Cl₂ and/or BCl₃ for the aluminum alloy layer. In some implementations, the black mask 23 can be an etalon or interferometric stack structure. In such interferometric stack black mask structures 23, the conductive absorbers can be used to transmit or bus signals between lower, stationary electrodes in the optical stack 16 of each row or column. In some implementations, a spacer layer 35 can serve to generally electrically isolate the absorber layer 16a from the conductive layers in the black mask 23.

FIG. 5E shows another example of an IMOD, where the movable reflective layer 14 is self supporting. In contrast with FIG. 5D, the implementation of FIG. 5E does not include support posts 18. Instead, the movable reflective layer 14 contacts the underlying optical stack 16 at multiple locations, and the curvature of the movable reflective layer 14 provides sufficient support that the movable reflective layer 14 returns to the unactuated position of FIG. 5E when the voltage across the interferometric modulator is insufficient to cause actuation. The optical stack 16, which may contain a plurality of several different layers, is shown here for clarity including an optical absorber 16a, and a dielectric 16b. In some implementations, the optical absorber 16a may serve both as a fixed electrode and as a partially reflective layer.

In implementations such as those shown in FIGS. 5A-5E, the IMODs function as direct-view devices, in which images are viewed from the front side of the transparent substrate 20, i.e., the side opposite to that upon which the modulator is arranged. In these implementations, the back portions of the device (that is, any portion of the display device behind the movable reflective layer 14, including, for example, the deformable layer 34 illustrated in FIG. 5C) can be configured and operated upon without impacting or negatively affecting the image quality of the display device, because the reflective layer 14 optically shields those portions of the device. For example, in some implementations a bus structure (not illustrated) can be included behind the movable reflective layer 14 which provides the ability to separate the optical properties of the modulator from the electromechanical properties of the modulator, such as voltage addressing and the movements that result from such addressing. Additionally, the implementations of FIGS. 5A-5E can simplify processing, such as, e.g., patterning.

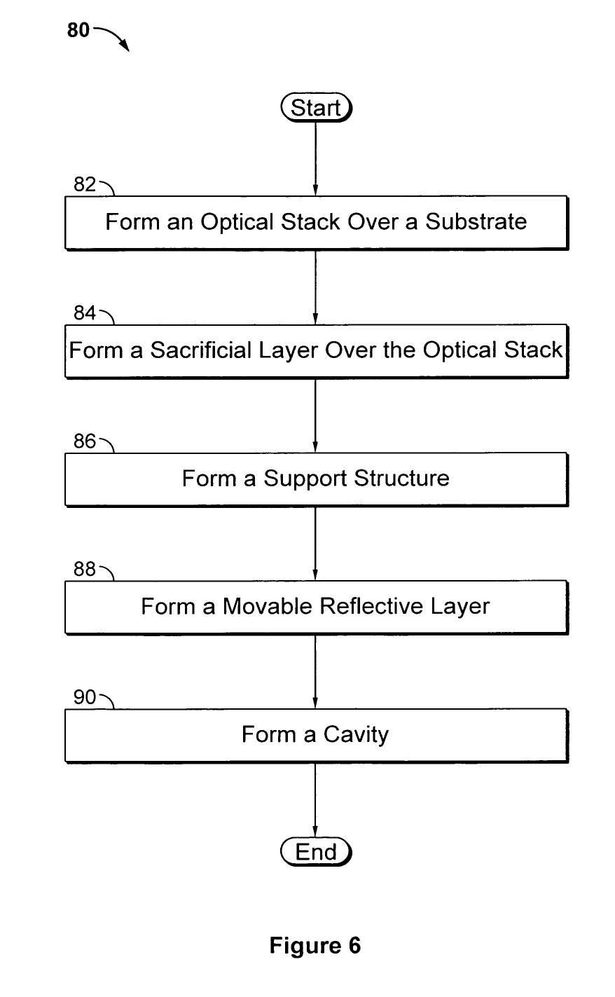

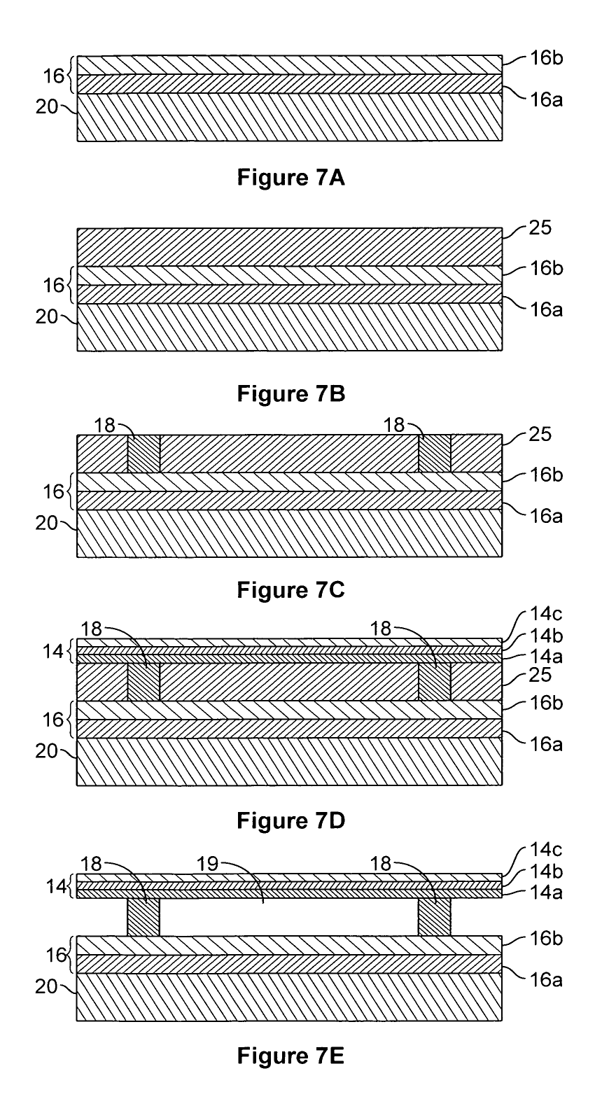

FIG. 6 shows an example of a flow diagram illustrating a manufacturing process 80 for an interferometric modulator, and FIGS. 7A-7E show examples of cross-sectional schematic illustrations of corresponding stages of such a manufacturing process 80. In some implementations, the manufacturing process 80 can be implemented to manufacture, e.g., interferometric modulators of the general type illustrated in FIGS. 1 and 5, in addition to other blocks not shown in FIG. 6. With reference to FIGS. 1, 5 and 6, the process 80 begins at block 82 with the formation of the optical stack 16 over the substrate 20. FIG. 7A illustrates such an optical stack 16 formed over the substrate 20. The substrate 20 may be a transparent substrate such as glass or plastic, it may be flexible or relatively stiff and unbending, and may have been subjected to prior preparation processes, e.g., cleaning, to facilitate efficient formation of the optical stack 16. As discussed above, the optical stack 16 can be electrically conductive, partially transparent and partially reflective and may be fabricated, for example, by depositing one or more layers having the desired properties onto the transparent substrate 20. In FIG. 7A, the optical stack 16 includes a multilayer structure having sub-layers 16a and 16b, although more or fewer sub-layers may be included in some other implementations. In some implementations, one of the sub-layers 16a, 16b can be configured with both optically absorptive and conductive properties, such as the combined conductor/absorber sub-layer 16a. Additionally, one or more of the sub-layers 16a, 16b can be patterned into parallel strips, and may form row electrodes in a display device. Such patterning can be performed by a masking and etching process or another suitable process known in the art. In some implementations, one of the sub-layers 16a, 16b can be an insulating or dielectric layer, such as sub-layer 16b that is deposited over one or more metal layers (e.g., one or more reflective and/or conductive layers). In addition, the optical stack 16 can be patterned into individual and parallel strips that form the rows of the display.

The process 80 continues at block 84 with the formation of a sacrificial layer 25 over the optical stack 16. The sacrificial layer 25 is later removed (e.g., at block 90) to form the cavity 19 and thus the sacrificial layer 25 is not shown in the resulting interferometric modulators 12 illustrated in FIG. 1. FIG. 7B illustrates a partially fabricated device including a sacrificial layer 25 formed over the optical stack 16. The formation of the sacrificial layer 25 over the optical stack 16 may include deposition of a xenon difluoride (XeF₂)-etchable material such as molybdenum (Mo) or amorphous silicon (Si), in a thickness selected to provide, after subsequent removal, a gap or cavity 19 (see also FIGS. 1 and 7E) having a desired design size. Deposition of the sacrificial material may be carried out using deposition techniques such as physical vapor deposition (PVD, e.g., sputtering), plasma-enhanced chemical vapor deposition (PECVD), thermal chemical vapor deposition (thermal CVD), or spin-coating.

The process 80 continues at block 86 with the formation of a support structure e.g., a post 18 as illustrated in FIGS. 1, 5 and 7C. The formation of the post 18 may include patterning the sacrificial layer 25 to form a support structure aperture, then depositing a material (e.g., a polymer or an inorganic material, e.g., silicon oxide) into the aperture to form the post 18, using a deposition method such as PVD, PECVD, thermal CVD, or spin-coating. In some implementations, the support structure aperture formed in the sacrificial layer can extend through both the sacrificial layer 25 and the optical stack 16 to the underlying substrate 20, so that the lower end of the post 18 contacts the substrate 20 as illustrated in FIG. 5A. Alternatively, as depicted in FIG. 7C, the aperture formed in the sacrificial layer 25 can extend through the sacrificial layer 25, but not through the optical stack 16. For example, FIG. 7E illustrates the lower ends of the support posts 18 in contact with an upper surface of the optical stack 16. The post 18, or other support structures, may be formed by depositing a layer of support structure material over the sacrificial layer 25 and patterning portions of the support structure material located away from apertures in the sacrificial layer 25. The support structures may be located within the apertures, as illustrated in FIG. 7C, but also can, at least partially, extend over a portion of the sacrificial layer 25. As noted above, the patterning of the sacrificial layer 25 and/or the support posts 18 can be performed by a patterning and etching process, but also may be performed by alternative etching methods.

The process 80 continues at block 88 with the formation of a movable reflective layer or membrane such as the movable reflective layer 14 illustrated in FIGS. 1, 5 and 7D. The movable reflective layer 14 may be formed by employing one or more depositions, e.g., reflective layer (e.g., aluminum, aluminum alloy) deposition, along with one or more patterning, masking, and/or etching processes. The movable reflective layer 14 can be electrically conductive, and referred to as an electrically conductive layer. In some implementations, the movable reflective layer 14 may include a plurality of sub-layers 14a, 14b, 14c as shown in FIG. 7D. In some implementations, one or more of the sub-layers, such as sub-layers 14a, 14c, may include highly reflective sub-layers selected for their optical properties, and another sub-layer 14b may include a mechanical sub-layer selected for its mechanical properties. Since the sacrificial layer 25 is still present in the partially fabricated interferometric modulator formed at block 88, the movable reflective layer 14 is typically not movable at this stage. A partially fabricated IMOD that contains a sacrificial layer 25 may also be referred to herein as an “unreleased” IMOD. As described above in connection with FIG. 1, the movable reflective layer 14 can be patterned into individual and parallel strips that form the columns of the display.

The process 80 continues at block 90 with the formation of a cavity, e.g., cavity 19 as illustrated in FIGS. 1, 5 and 7E. The cavity 19 may be formed by exposing the sacrificial material 25 (deposited at block 84) to an etchant. For example, an etchable sacrificial material such as Mo or amorphous Si may be removed by dry chemical etching, e.g., by exposing the sacrificial layer 25 to a gaseous or vaporous etchant, such as vapors derived from solid XeF₂ for a period of time that is effective to remove the desired amount of material, typically selectively removed relative to the structures surrounding the cavity 19. Other etching methods, e.g. wet etching and/or plasma etching, also may be used. Since the sacrificial layer 25 is removed during block 90, the movable reflective layer 14 is typically movable after this stage. After removal of the sacrificial material 25, the resulting fully or partially fabricated IMOD may be referred to herein as a “released” IMOD.

Stiction can be one of the most important reliability issues in electromechanical systems in general and interferometric modulators (IMODs) in particular.

“Stiction,” as used herein, refers to a tendency of a movable layer to stick to a stationary layer in an electromechanical system.

Stiction occurs when the total of the adhesion forces between two layers is greater than a restoring force. Adhesion forces become more significant with decreasing device dimensions. Restoring forces, however, decrease with decreasing device sizes. Thus, stiction becomes a greater reliability concern for electromechanical systems as they are scaled to smaller dimensions, such as IMOD displays of increasing resolution.

Adhesion forces may arise from several mechanisms such as, capillary forces, van der Waals interactions, chemical bonds, solid bridging, etc. Adhesion forces, including short range and long range adhesion forces, depend on contact area and surface separation between two layers. Short range adhesion forces may be decreased by decreasing contact area between contacting surfaces, e.g., by increasing an effective hardness and/or roughening the surfaces. Long-range adhesion forces may be decreased by increasing an average surface separation between two layers in the actuated or collapsed condition of the electromechanical systems device.

In order to reduce adhesion forces, techniques are applied to control topography and chemical composition of contacting surfaces. Existing solutions for reducing stiction, however, risk adversely affecting the primary functions of electromechanical systems devices. Thus, a need exists to modify contact surfaces in an inexpensive and simple manner on the nanometer scale, without reducing the performance of the electromechanical systems device.

The electromechanical systems devices of the illustrated implementations are interferometric modulators (IMODs). IMODs may be manufactured using manufacturing techniques known in the art for making electromechanical devices. For example, the various material layers making up the IMODs may be sequentially deposited onto a transparent substrate with appropriate patterning and etching processes conducted between deposition processes. In some implementations, multiple layers may be deposited during manufacturing without patterning between the depositions. For example, the movable reflective layer described above may include a composite structure having two or more layers.

While illustrated in the context of optical electromechanical devices, particularly IMODs, the skilled artisan will appreciate that the reduced stiction between contacting surfaces is also advantageous for other electromechanical devices, such as electromechanical switches, gyroscopes, varactors, sensors, etc.

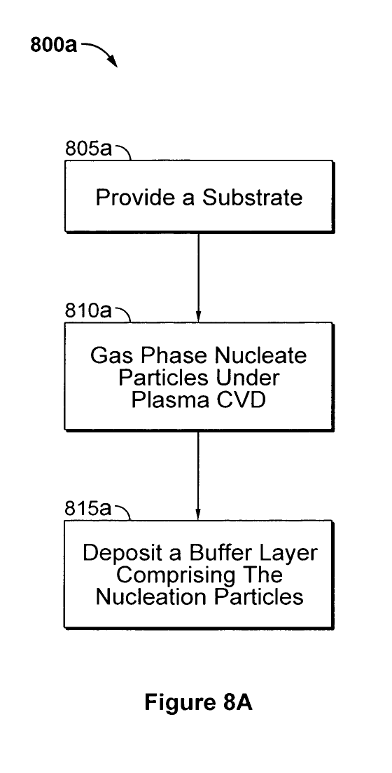

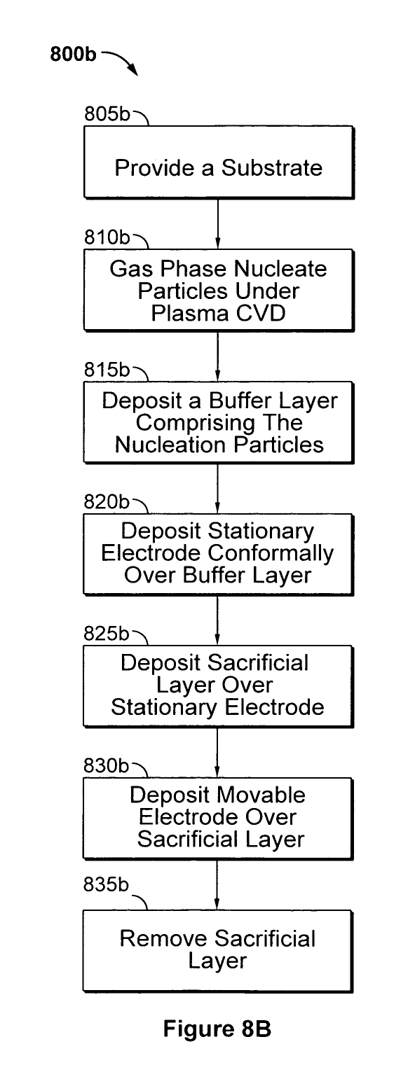

FIG. 8A shows an example of a flow diagram illustrating a method of making an electromechanical systems apparatus in accordance with one implementation. Such blocks may be present in a process for manufacturing IMODs of the general type illustrated in FIGS. 1-7E, along with other blocks not shown in FIG. 8A. For example, it will be understood that additional processes of depositing underlying or intervening layers, such as black mask layers, bussing layers, and absorber layers may be present. With reference to FIG. 8A, the process 800a begins at block 805a where a substrate is provided. In one implementation, the substrate may include a transparent material such as glass or plastic.

The process 800a continues at block 810a with gas phase nucleation of particles under plasma chemical vapor deposition (CVD) conditions. Gas phase nucleation is the formation of particles within a gaseous environment. In one implementation, reactions involving silane (SiH₄) polymerization initially drive cluster formation. Polymerization occurs via insertion of SiH₂ into the Si—H bond of Si₂ₓH₂ₓ₊₂. The primary production source of SiH₂ is due to electron impact dissociation of SiH₄ in a precursor activating environment, such as a plasma. The clusters of Si₂ₓH₂ₓ₊₂ can react with certain numbers of N and O in the gas phase to produce particles silicon nitride, silicon oxide and silicon oxynitride. However, the cluster of particles are not necessarily produced in stoichiometric ratios of silicon nitride, silicon oxide and silicon oxynitride (e.g., SiN, SiO₂ and SiON). In fact, the cluster of particles may be more Si-rich compared to the remainder of a surrounding layer. Though the surrounding layer and the particles may have the same composition, it is possible to distinguish the particles from the surrounding layer by tunnel electron microscopy (TEM). For example, by using an energy dispersive x-ray (EDX) analysis, particles of more Si-rich crystal structures can be distinguished from crystal structures having stoichiometric ratios of silicon oxide and silicon oxynitride. The composition of the particles can be controlled by a number of processing parameters, including plasma processing parameters listed below.

Various types of plasma CVD reactors are known in the art. For example, a parallel-plate plasma CVD reactor includes two electrode plates opposed to each other. In some implementations, one of the electrodes also operates to hold the substrate. Such reactors are sometimes referred to as in situ plasma reactors, because the plasma is generated within the reactor. Other reactors are referred to as downstream plasma reactors, where a remote plasma source feeds plasma products to the deposition chamber. Another example of an in situ plasma reactor is an inductively coupled plasma (ICP) process reactor, which forms plasmas by inducing current in a process gas disposed within the chamber via one or more inductive coils outside of the chamber. Moreover, plasma CVD reactors may be configured for single substrate processing or dual substrate processing. One example of an in situ plasma CVD reactor is the ULTIMA™ High Density Plasma-CVD Reactor from Applied Materials, Inc., of Santa Clara, Calif. In situ plasma reactors can afford greater control over the intentional gas phase nucleation in accordance with implementations described herein.

During block 810a, nanoscale particles may be nucleated in the gas phase by applying a high pressure and/or high power plasma CVD deposition process. The size, distribution, and number of particles nucleated may be controlled by selection of deposition process conditions. Selecting the deposition process conditions include control over parameters such as temperature, pressure, feed gas mixture, flow rate and power.

The plasma CVD deposition process coincides with the nucleation of particles in block 810a and the deposition of a buffer layer in block 815a. In some implementations, deposition of a layer without nucleation of particles may be conducted before or after blocks 810a and 815a. In blocks 810a and 815a, the selected plasma CVD conditions include the use of one or more gases, e.g., feed gases. During the deposition of the buffer layer including, for example, one or more of a silicon oxide, a silicon nitride, a silicon oxynitride, and amorphous silicon, a silicon precursor (e.g., a silane such as monosilane, SiH₄) feed gas can be used in any combination along with other reactant gases such as nitrogen and/or oxygen precursors (e.g., N₂, N₂O, NH₃, and NF₃, and/or O₂). In nucleating particles and depositing the buffer layer in blocks 810a and 815a, a feed gas mixture is introduced into a plasma CVD process chamber with each gas flowing at a preselected rate.

Precursor gas molecules break up into reactive radicals in a plasma that is formed by applying a sufficiently high power to generate an alternating field between the electrodes. In one implementation, the RF power can be between about 0.1 W/cm² and about 10 W/cm². More specifically, the RF power can be between about 3 W/cm² and about 6 W/cm². During the deposition, the substrate can be heated to a temperature between about 250° C. and about 400° C. and maintained during the deposition process. In addition, the chamber pressure is configured to be between about 0.5 Torr and about 10 Torr. Particularly, the chamber pressure can be about 5 Torr to about 10 Torr. However, in implementations employing inductively coupled plasma (ICP) reactors, the processing pressure can be between about 0.01 Torr to about 0.1 Torr.

The flow rate of the gas mixture affects the nucleation of particles in the gas phase as well as the deposition of the buffer layer. In one implementation, feed gases may include SiH₄, NH₃, N₂O and N₂. Particularly, for the Applied Materials ULTIMA™ chamber, the flow rate of the SiH₄ may be between about 1 and about 300 standard cubic centimeters per minute (sccm). In general, as the flow rate of SiH₄ is increased, the number of particles increases. The flow rate of the other gases can be between about 0 and about 5,000 sccm.

A plasma can form from the gases in the alternating electric field between electrodes. Deposition conditions, and particularly plasma power and pressure, can be chosen to cause gas phase nucleation and tuned for the desired average size of the particles and consequent roughness of the deposited layer, in contrast to typical PECVD processes, which try to minimize gas phase nucleation. While pressure and power is normally optimized to produce smooth layers, some implementations employ pressure and/or power that are higher than that optimized for smooth layers, given the other deposition parameters such as a flow rates, temperature, etc. Within the desired ranges, increasing the RF power and/or chamber pressure can correspond to an increase in the size of the particles.

FIG. 8B shows an example of a flow diagram illustrating a method of making an electromechanical systems apparatus in accordance with another implementation. The process 800b begins at blocks 805b, 810b, and 815b, which can be similar to blocks 805a, 810a, and 815a, respectively, as described with respect to FIG. 8A. The process 800b then continues in block 820b where a stationary electrode is deposited conformally over the buffer layer. The conformal deposition of the stationary electrode over the buffer layer transfers roughness from the buffer layer to the surface of the stationary electrode. The roughened buffer layer transfers roughness through the stationary electrode so that the roughness is substantially similar to the roughness of the buffer layer.

The process 800b continues at block 825b with the deposition of a sacrificial layer over the stationary electrode. The sacrificial layer is later removed (e.g., block 835b) to form an optical cavity or gap having a desired size. Deposition of the sacrificial layer may be carried out using a variety of deposition techniques, such as physical vapor deposition (PVD), plasma-enhanced chemical vapor deposition (PECVD), thermal chemical vapor deposition (thermal CVD), or spin-coating. The sacrificial layer may include a material that can be selectively removed relative to the structural materials to remain in the device, such as aluminum, silicon oxide, silicon nitride, and silicon oxynitride. For example, molybdenum, tungsten, titanium or amorphous silicon sacrificial materials can be selectively removed by fluorine-based etchants.

Upon deposition in block 825b, the sacrificial layer includes a roughness formed by conformal deposition of the sacrificial layer over the stationary electrode. In some implementations, the roughness of the sacrificial layer is substantially similar to the roughness of the stationary electrode and/or the buffer layer. In some other implementations, the roughness of the sacrificial layer may be less than or greater than the stationary electrode by altering the deposition conditions of the sacrificial layer or depositing a planarization layer over the stationary electrode. Additionally, the planarizing of the sacrificial layer may be accomplished by chemical mechanical polishing (CMP) and/or forming the sacrificial layer by spin coating.

With continued reference to FIG. 8B, after any desired patterning of the sacrificial layer (such as for forming support structures through the sacrificial layer), the process 800b continues at block 830b with the deposition of the movable electrode over the sacrificial layer. The roughness of the movable electrode may be substantially similar to the roughness of the sacrificial layer, the stationary electrode, and/or the buffer layer. However, even with perfect conformality of the layers overlying the buffer layer, the surface texture is naturally altered in propagation through the thickness of the overlying layers. Imperfect conformality further smoothes out texture through the thickness of overlying layers. Moreover, in some implementations, roughness need not be transferred by conformal deposition of the movable electrode over the sacrificial layer. In addition, the movable electrode may have a higher or lower roughness by altering the deposition conditions, CMP, or depositing a planarization layer over the sacrificial layer.

Following any desired patterning of the movable electrode layer(s), the process 800b continues in block 835b with the removal of the sacrificial layer and the formation of a gap through which the movable electrode can move. For the illustrated IMOD implementation, the gap also functions as the optical cavity for interferometric operation in the open state, together with the dielectric layer of the stationary electrode. The gap may be formed by exposing the sacrificial material to an etchant. For example, the sacrificial material may be removed by dry chemical etching, e.g., exposing the sacrificial layer to a gaseous or vaporous etchant, such as vapors derived from solid XeF₂ for a period of time that is effective to remove the desired amount of material. Vaporized XeF₂ will selectively etch the sacrificial material (e.g., molybdenum, amorphous silicon, tungsten or titanium) without removing other exposed materials, such as aluminum alloy, silicon oxide, silicon oxynitride, etc. The etchant can reach the sacrificial material through gaps between strips of the movable electrode and/or etch holes. Other etching methods, e.g., wet etching and/or plasma etching, may also be used.

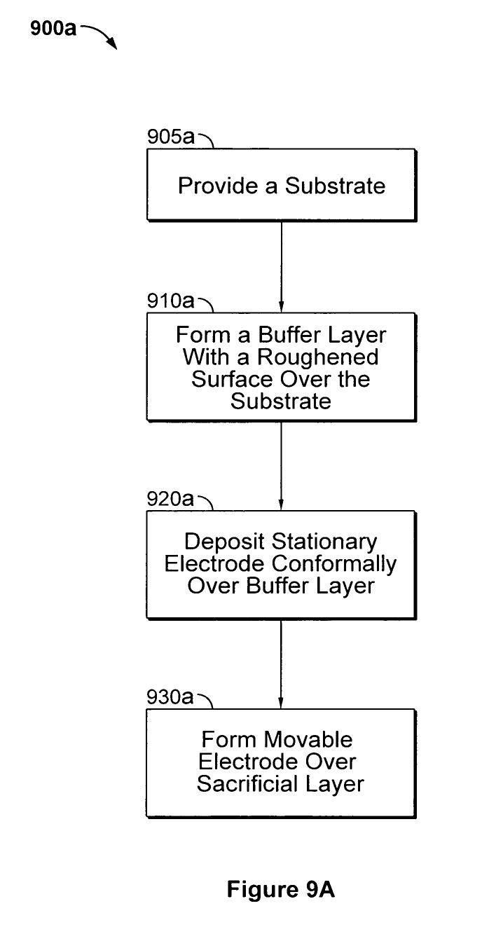

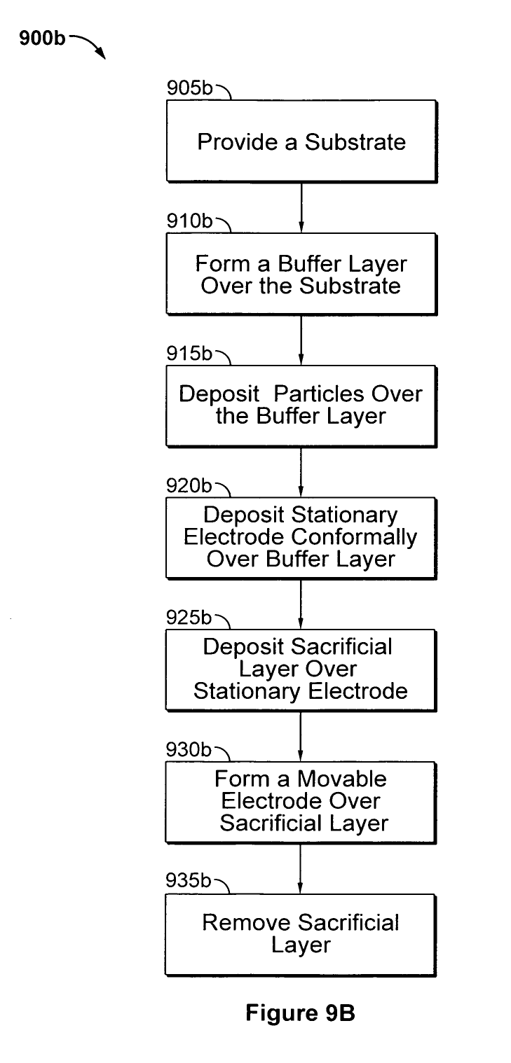

FIG. 9A shows an example of a flow diagram illustrating a method of making an electromechanical systems apparatus in accordance with another implementation The process 900a begins at block 905a by providing a substrate. The process 900a continues at block 910a with the formation of a buffer layer with a roughened surface over the substrate. The buffer layer may be formed using a variety of deposition techniques known in the art and/or discussed in this disclosure. To roughen the surface of the buffer layer in block 910a, methods can be used such as the gas phase nucleating particles under plasma CVD conditions described above with respect to block 810a of FIG. 8A. Alternatively, deposition of particles using a spin-on process or other techniques known in the art, may be used. The materials and processing for blocks 920a and 930a can be similar to those described for blocks 820b and 830b, respectively of FIG. 8A.

FIG. 9B shows an example of a flow diagram illustrating a method of making an electromechanical systems apparatus in accordance with another implementation. The process 900b begins at block 905b, which can be similar to block 905a in FIG. 9A. The process 900b continues at block 910b with the formation of a buffer layer over a substrate. In block 915b, a plurality of particles are deposited over the buffer layer. Blocks 910b and 915b may be conducted sequentially. For example, particles suspended or otherwise mixed in a liquid can be applied by spin-on deposition and drying. Rather than concurrently depositing the buffer layer with the particles, depositing particles in block 915b is performed after the deposition of the buffer layer. The materials and processing used in blocks 920b, 925b, 930b and 935b can be similar to those described for blocks 820b, 825b, 830b and 835b, respectively of FIG. 8B.

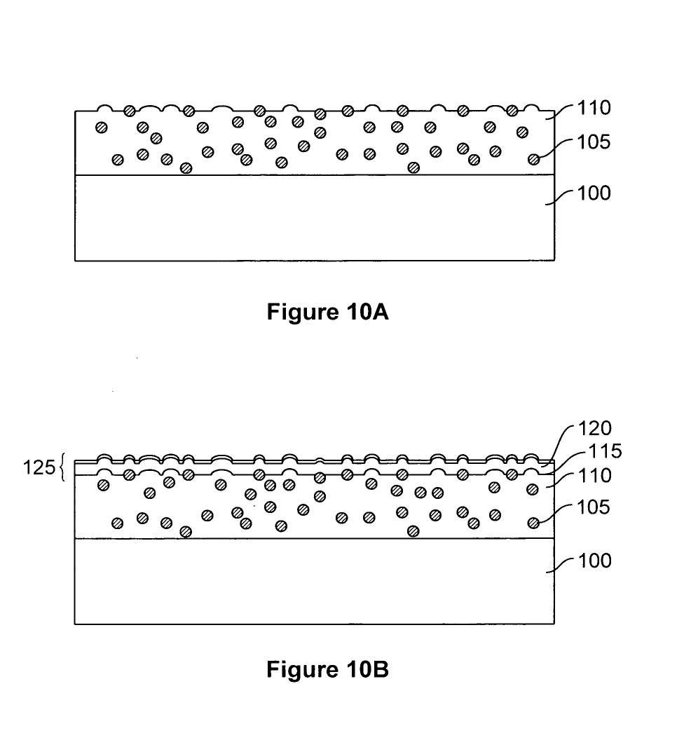

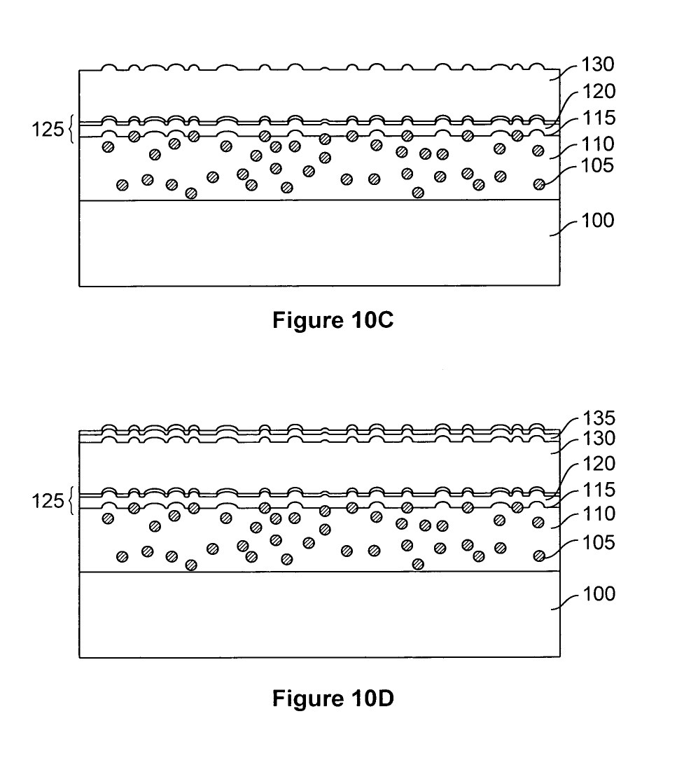

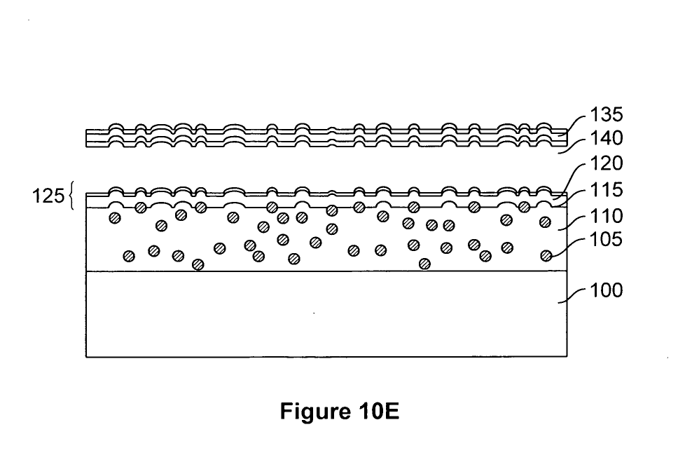

FIGS. 10A through 10E show examples of cross sections illustrating processing for manufacturing an electromechanical systems apparatus, e.g., IMOD. The cross sections correspond to the processing described in FIG. 8B. In FIG. 10A, a substrate 100 is provided with a buffer layer 110 deposited thereover. The buffer layer 110 is deposited under plasma CVD conditions described earlier. A plurality of nucleated particles 105 can be incorporated into the buffer layer 110. The size, distribution, and number of the particles 105 depend on the deposition process conditions, particularly pressure and power.

The average size of the nucleated particles 105 is greater than 5 Å and, in some implementations, greater than 15 Å in diameter. For the illustrated buffer layer 110 under an electromechanical systems stationary electrode, the average particle size can range from about 5 Å to about 1,000 Å in diameter. Specifically, the size of the nucleated particles 105 can range from about 15 Å to about 50 Å in diameter. A person having ordinary skill in the art will appreciate that adjustment to deposition conditions can provide desired particle sizes through routine optimization in view of the teachings herein. It will be further appreciated that the nucleated particles 105 may have non-uniform sizes, with some of the particles 105 covering the surface and some of the particles 105 embedded in the buffer layer 110. The particles 105 may include a substantially transparent material such as silicon nitride, silicon oxide and silicon oxynitride.

Similarly, the buffer layer 110 may include a material such as silicon nitride, silicon oxide and silicon oxynitride. In some implementations, the plasma nucleated particles 105 include a material that is substantially homogeneous in composition with the buffer layer 110, though the particles 105 can have crystal structures that are more Si-rich and having fewer compounds of silicon nitride, silicon oxide and silicon oxynitride in stoichiometric ratios (e.g., SiN, SiON and SiO₂) compared to the buffer layer 110, and thus identifiable particles in a TEM of the layer. Also, the particles 105 and the buffer layer 110 can be formed simultaneously by the same precursor mixture. However, as described in FIG. 9B, the nucleated particles 105 can be applied after the deposition of the buffer layer 110. Additionally, the material and thickness of the buffer layer 110 may be configured to minimize optical effects in an IMOD. In one implementation, the buffer layer 110 is between about 2,000 Å and about 10,000 Å in thickness. Because the thickness of the buffer layer 110 is relatively large, there is a minimal optical effect on the performance of the IMOD. Therefore, in some implementations, the particles 105 in the buffer layer 110 do not negatively affect optical performance. In some implementations, the buffer layer 110 includes a dielectric material and has substantially the same index of refraction as a dielectric layer described below, for example, SiOₓN_{y} having a substantially similar index as SiO₂.

The nucleated particles 105 in the buffer layer 110 in FIG. 10A produce a non-planar or “roughened” surface. The topography of the roughened surface depends on the size, distribution, and number of particles 105 incorporated in the buffer layer 110. A further analysis of the topography may be explored using techniques known in the art, such as scanning electron microscopy (SEM). Roughness may be statistically characterized by the root mean square (RMS) value, averaging the vertical deviations of a real surface from the ideal plane of the surface. In a buffer layer application for an IMOD, the surface roughness of the buffer layer 110 can be between about 15 Å and 500 Å RMS. In some implementations, the surface roughness of the buffer layer 110 is between about 20 Å and about 100 Å RMS.

In FIG. 10B, with respect to the manufacture of IMODs, the formation of a stationary electrode includes the deposition of an optical stack 125. The stationary electrode includes an electrically conductive material. In particular, for the illustrated implementation, the optical stack 125 includes an optical absorber layer 115, which is configured to partially absorb and partially transmit visible light. The absorber layer 115 is between about 1 Å and about 80 Å in thickness. In some implementations, the absorber layer 115 includes a semitransparent thickness of a metallic film, such as MoCr or Cr, or of a semiconductor film, such as Si or Ge.

With continued reference to FIG. 10B, the optical stack 125 may further include an optical layer 120. The optical layer 120 can include an insulating or dielectric layer. In some implementations, the optical layer 120 is deposited over the absorber layer 115. The optical layer 120 can include a transparent dielectric material such as SiO₂ and/or another substantially transparent material like Al₂O₃, AlOₓ, Si₃N₄, SiNₓ, SiOₓN_{y}, Ta₂O₅, TaOₓ, TiO₂, ZrO₂ or HfO₂. The optical layer 120 may be between about 200 Å and about 1,000 Å in thickness. Additionally, in some implementations, the optical layer 120 may include a layer of silicon dioxide and an overlying layer of aluminum oxide, which can serve as an etch stop layer during subsequent patterning of overlying sacrificial material.

Also, as illustrated in FIG. 10B, the contour of the non-planar surface of the optical stack 125 can be substantially similar to the contour of the non-planar surface of the buffer layer 110. By roughening the buffer layer 110, and without incorporating particles into the optical stack 125, the optical stack 125 does not negatively affect image quality in an IMOD. While the optical stack 125 is typically high quality, the buffer layer 110 need not be. In some implementations, the roughness of the optical stack 125 is greater than about 15 Å RMS, as a result of the nucleated particles 105 incorporated into the underlying buffer layer 110. In some implementations, the surface roughness of the optical stack 125 is between about 20 Å and about 100 Å.

In some implementations, the optical stack 125 also can include a transparent conductive material such as an ITO layer (not shown), particularly between the absorber layer 115 and the optical layer 120. In the illustrated implementation in FIG. 10B without ITO, the absorber layer 115 is the only conductor in the stationary electrode.

In FIG. 10C, a sacrificial layer 130 is deposited over the optical stack 125. The thickness of the sacrificial layer 130 is largely determined by the desired size of the gap, where different gap sizes typically correspond to different reflected colors in the open state for the IMOD. For example, the gap size for the color blue can be between about 3100 Å to about 3900 Å, the gap size for the color red can be between about 2300 Å to about 2700 Å and the color green can be between about 1700 Å to about 1900 Å. Generally, the size of the gap can be between about 1,000 Å and about 5,000 Å. The sacrificial layer 130 can include multiple layers and etch stops for producing different thicknesses for different electromechanical systems devices in an array, such as red, blue, and green IMODs with different gap sizes.

As illustrated in FIG. 10D, a movable electrode 135 is deposited over the sacrificial layer 130 as described above. Since the sacrificial layer 130 is still present at this stage in the process 800, the movable electrode 135 is not yet movable in the unreleased IMOD. Forming the movable electrode 135 may include one or more depositions as well as one or more patterning or masking processes. For the illustrated IMOD implementation, the movable electrode 135 may include aluminum, an aluminum alloy, or a similar reflective material. In some implementations, the movable electrode 135 includes or is attached to a flexible membrane that is in tensile stress formed over a reflective aluminum thin film. In some implementations, the movable electrode 135 includes a dielectric mechanical layer integrated with conductor layers of similar composition above and below for more balanced stresses. For example, the movable electrode 135 can include a silicon oxynitride mechanical layer sandwiched between an aluminum alloy (0.5% Cu) mirror below and a similar aluminum alloy layer above. In some other implementations, the movable electrode 135 can take any of the forms described above with respect to FIGS. 7A-7E above. In non-optical electromechanical systems devices, the movable electrode 135 need not include a reflective surface.

In FIG. 10E, after removal of the sacrificial layer 130, the movable electrode 135 is in the “released” state and is movable across a gap 140 with the application of a voltage across the electrodes. As noted above for the illustrated IMOD implementation, the gap 140 serves as an optical cavity for reflecting interferometrically enhanced reflected colors. Furthermore, when the IMOD is in the collapsed state, the optical layer 120 operates to define the reflected background color. One or more support structures or posts as described with respect to FIGS. 1 and 7A-7E can support the movable electrode 135.

When the IMOD is released, the movable electrode 135 is movable between an unactuated or open state and an actuated or collapsed state. When a voltage is applied to an IMOD structure, the movable electrode 135 is electrostatically displaced toward the stationary electrode, altering the distance between the movable electrode 135 and the stationary electrode. This enables the IMOD structure to actuate between an open and collapsed state. In the collapsed state, the surface of the movable electrode 135 may be in contact with the optical layer 120 (or overlying etch stop) of the stationary electrode across the active surface area of the pixel. Because of the non-planar interface created by the movable electrode 135 and the stationary electrode, stiction may be reduced because the contact area is reduced, such that the movable electrode 135 more readily returns to the open state upon relaxation.

Due to the non-exact replication of the contour between the movable electrode 135 and the stationary electrode, and due to displacement of the surface through bending of the movable electrode 135 upon actuation, the non-planar surface of the movable electrode 135 will generally not fit the non-planar surface of the stationary electrode. Furthermore, even with a smooth movable electrode 135, roughness of the stationary electrode is sufficient to reduce stiction.

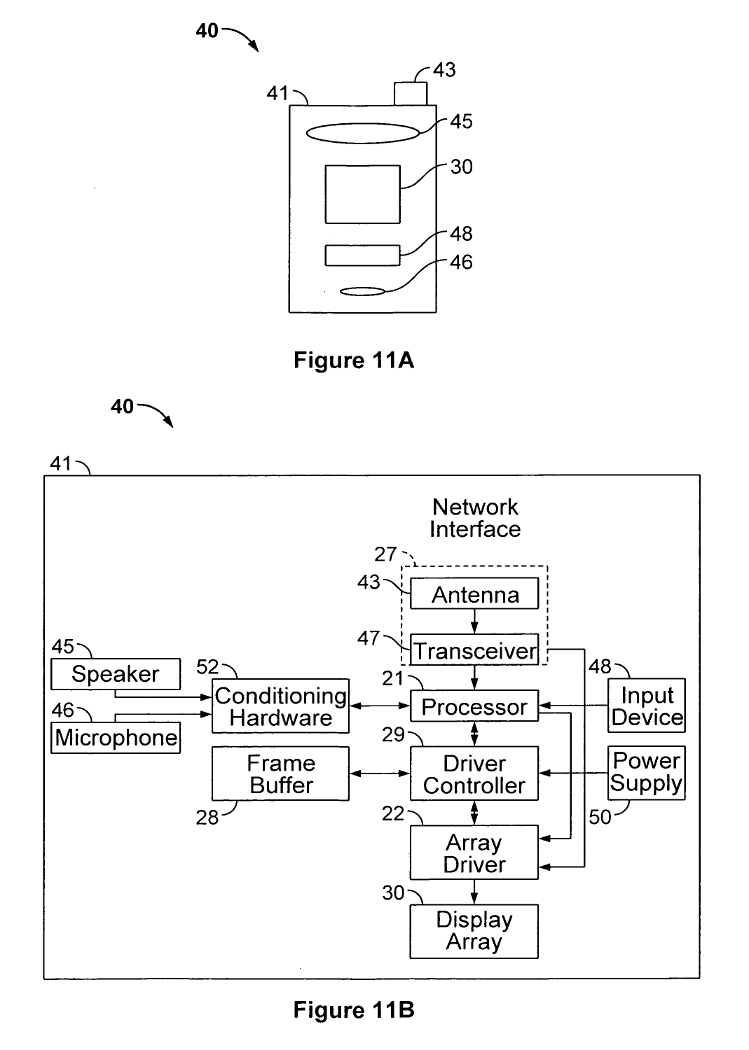

FIGS. 11A and 11B show examples of system block diagrams illustrating a display device 40 that includes a plurality of interferometric modulators. The display device 40 can be, for example, a cellular or mobile telephone. However, the same components of the display device 40 or slight variations thereof are also illustrative of various types of display devices such as televisions, e-readers and portable media players.

The display device 40 includes a housing 41, a display 30, an antenna 43, a speaker 45, an input device 48, and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber, and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be configured to include a flat-panel display, such as plasma, EL, OLED, STN LCD, or TFT LCD, or a non-flat-panel display, such as a CRT or other tube device. In addition, the display 30 can include an interferometric modulator display, as described herein.

The components of the display device 40 are schematically illustrated in FIG. 11B. The display device 40 includes a housing 41 and can include additional components at least partially enclosed therein. For example, the display device 40 includes a network interface 27 that includes an antenna 43 which is coupled to a transceiver 47. The transceiver 47 is connected to a processor 21, which is connected to conditioning hardware 52. The conditioning hardware 52 may be configured to condition a signal (e.g., filter a signal). The conditioning hardware 52 is connected to a speaker 45 and a microphone 46. The processor 21 is also connected to an input device 48 and a driver controller 29. The driver controller 29 is coupled to a frame buffer 28, and to an array driver 22, which in turn is coupled to a display array 30. A power supply 50 can provide power to all components as required by the particular display device 40 design.

The network interface 27 includes the antenna 43 and the transceiver 47 so that the display device 40 can communicate with one or more devices over a network. The network interface 27 also may have some processing capabilities to relieve, e.g., data processing requirements of the processor 21. The antenna 43 can transmit and receive signals. In some implementations, the antenna 43 transmits and receives RF signals according to the IEEE 16.11 standard, including IEEE 16.11(a), (b), or (g), or the IEEE 802.11 standard, including IEEE 802.11a, b, g or n. In some other implementations, the antenna 43 transmits and receives RF signals according to the BLUETOOTH standard. In the case of a cellular telephone, the antenna 43 is designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1×EV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G or 4G technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that is readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation, and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29, such as an LCD controller, is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of pixels.

In some implementations, the driver controller 29, the array driver 22, and the display array 30 are appropriate for any of the types of displays described herein. For example, the driver controller 29 can be a conventional display controller or a bi-stable display controller (e.g., an IMOD controller). Additionally, the array driver 22 can be a conventional driver or a bi-stable display driver (e.g., an IMOD display driver). Moreover, the display array 30 can be a conventional display array or a bi-stable display array (e.g., a display including an array of IMODs). In some implementations, the driver controller 29 can be integrated with the array driver 22. Such an implementation is common in highly integrated systems such as cellular phones, watches and other small-area displays.

In some implementations, the input device 48 can be configured to allow, e.g., a user to control the operation of the display device 40. The input device 48 can include a keypad, such as a QWERTY keyboard or a telephone keypad, a button, a switch, a rocker, a touch-sensitive screen, or a pressure- or heat-sensitive membrane. The microphone 46 can be configured as an input device for the display device 40. In some implementations, voice commands through the microphone 46 can be used for controlling operations of the display device 40.

The power supply 50 can include a variety of energy storage devices as are well known in the art. For example, the power supply 50 can be a rechargeable battery, such as a nickel-cadmium battery or a lithium-ion battery. The power supply 50 also can be a renewable energy source, a capacitor, or a solar cell, including a plastic solar cell or solar-cell paint. The power supply 50 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware and/or software components and in various configurations.

The various illustrative logics, logical blocks, modules, circuits and algorithms described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and processes described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration. In some implementations, particular methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

Various modifications to the implementations described in this disclosure may be readily apparent to those skilled in the art, and the generic principles defined herein may be applied to other implementations without departing from the spirit or scope of this disclosure. Thus, the disclosure is not intended to be limited to the implementations shown herein, but is to be accorded the widest scope consistent with the claims, the principles and the novel features disclosed herein. The word “exemplary” is used exclusively herein to mean “serving as an example, instance, or illustration.” Any implementation described herein as “exemplary” is not necessarily to be construed as preferred or advantageous over other implementations. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of the IMOD as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. A method of producing roughness in an electromechanical apparatus, comprising:
providing a substrate;
gas phase nucleating particles under plasma chemical vapor deposition (CVD) conditions; and
depositing a first layer including the gas phase nucleated particles to create roughness in the first layer of the electromechanical apparatus,
wherein the roughness of the first layer is greater than or equal to about 20 Å root mean square (RMS).

2. The method as recited in claim 1, further comprising transferring the roughness to a second layer by conformal deposition of the second layer over the first layer.

3. The method as recited in claim 2, further comprising forming a third layer over the second layer, the second and third layers defining a gap therebetween, the third layer having at least open and closed states for the electromechanical apparatus, wherein the third layer forms part of a movable electrode and the second layer forms part of a stationary electrode for the electromechanical apparatus.

4. The method as recited in claim 3, wherein transferring the roughness comprises providing roughness at a surface of the stationary electrode facing the gap for reducing stiction in between the stationary and the movable electrodes.

5. The method as recited in claim 1, wherein the roughness of the first layer is between about 20 Å and about 100 Å RMS.

6. The method as recited in claim 1, further comprising:
correlating one or more deposition conditions that include at least one of pressure, power, and feed gas mixture with roughness in the first layer; and
selecting one or more deposition conditions based at least in part on a desired roughness in the first layer and on correlating the one or more deposition conditions with roughness in the first layer.

7. The method as recited in claim 6, wherein selecting the one or more deposition conditions comprises applying power in the range of about 0.1 W/cm² to about 10 W/cm².

8. The method as recited in claim 6, wherein selecting the one or more deposition conditions comprises maintaining the substrate at a pressure in the range of about 0.5 Torr to about 10 Torr.

9. The method as recited in claim 1, wherein the gas phase nucleated particles are embedded in the first layer.

10. The method as recited in claim 1, wherein gas phase nucleating the particles is performed concurrently with depositing the first layer.

11. An electromechanical systems apparatus, comprising:
a substrate;
a first layer; and
a plurality of particles embedded in the first layer to create roughness in the first layer, the particles being substantially homogeneous in composition with the remainder of the first layer,
wherein the roughness of the first layer is greater than or equal to about 20 Å root mean square (RMS).

12. The apparatus as recited in claim 11, further comprising a plurality of additional particles on top of the first layer.

13. An electromechanical systems apparatus, comprising:
a substrate;
a buffer layer formed on the substrate, the buffer layer having a roughened surface;
a stationary electrode formed over the buffer layer, the stationary electrode having a rough surface corresponding to the roughened surface of the buffer layer;
a movable electrode; and
a gap defined between the movable electrode and the stationary electrode, wherein the movable electrode is configured to move across the gap to define at least an actuated and unactuated state.

14. The apparatus as recited in claim 13, forming an optical device, wherein the substrate, the buffer layer, and the stationary electrode are at least partially transparent.

15. The apparatus as recited in claim 13, wherein the stationary electrode comprises an optical layer.

16. The apparatus as recited in claim 13, wherein the surface of the movable electrode facing the gap has a rough surface corresponding to the rough surface of the stationary electrode.

17. The apparatus as recited in claim 13, wherein the buffer layer has a thickness between about 2,000 Å and about 10,000 Å.

18. The apparatus as recited in claim 13, wherein the buffer layer comprises a material chosen from the group consisting of SiN, SiOₓN_{y} and SiO_{z}.

19. The apparatus as recited in claim 13, wherein the buffer layer comprises a plurality of particles, wherein the particles comprise a material that is substantially homogeneous in composition with the remainder of the buffer layer.

20. The apparatus as recited in claim 19, wherein the particles have an average diameter between about 15 Å and about 50 Å.

21. The apparatus as recited in claim 19, wherein the particles are embedded in the buffer layer.

22. The apparatus as recited in claim 13, further comprising:
a display;
a processor that is configured to communicate with the display, the processor being configured to process image data; and
a memory device that is configured to communicate with the processor.

23. The apparatus as recited in claim 22, further comprising:
a driver circuit configured to send at least one signal to the display.

24. The apparatus as recited in claim 23, further comprising
a controller configured to send at least a portion of the image data to the driver circuit.

25. The apparatus as recited in claim 22, further comprising:
an image source module configured to send the image data to the processor.

26. The apparatus as recited in claim 25, wherein the image source module comprises at least one of a receiver, transceiver, and transmitter.

27. The apparatus as recited in claim 22, further comprising:
an input device configured to receive input data and to communicate the input data to the processor.

28. A method of manufacturing an electromechanical systems apparatus, comprising:
providing a substrate;
forming a buffer layer with a roughened surface over the substrate;
depositing a stationary electrode conformally over the buffer layer; and
forming a movable electrode over the stationary layer, the movable electrode and the stationary electrode defining a gap therebetween, the movable electrode having at least actuated and unactuated states.

29. The method as recited in claim 28, wherein depositing the stationary electrode comprises transferring roughness of the roughened surface to the stationary electrode by conformal deposition of the stationary layer over the buffer layer.

30. The method as recited in claim 29, further comprising:
depositing a sacrificial layer over the stationary electrode, wherein forming the movable electrode comprises depositing the movable electrode over the sacrificial layer; and
removing the sacrificial layer by applying an etchant.

31. The method as recited in claim 30, further comprising transferring roughness of the roughened surface to the movable electrode by conformal deposition of the sacrificial layer over the stationary electrode.

32. The method as recited in claim 28, wherein forming the buffer layer comprises forming particles by gas phase nucleation during plasma chemical vapor deposition (CVD), the particles being embedded in the buffer layer.

33. The method as recited in claim 32, wherein the particles have an average diameter between about 15 Å and about 50 Å.

34. The method as recited in claim 28, wherein forming the buffer layer with the roughened surface comprises depositing a layer and depositing a plurality of particles over the layer before depositing the stationary electrode.

35. An electromechanical systems apparatus, comprising:
means for supporting the electromechanical systems apparatus;
first means for conducting electricity, wherein the first means for conducting is positioned over the means for supporting;
means for roughening the first means for conducting, the means for roughening positioned between the means for supporting and the first means for conducting; and
second means for conducting electricity, the second means for conducting configured to move between an open state and a closed state in response to electrostatic forces between the first and the second means for conducting.

36. The apparatus as recited in claim 35, wherein the means for roughening has a roughness greater than or equal to about 20 Å root mean square (RMS).

37. The apparatus as recited in claim 35, wherein the means for roughening comprises a plurality of particles having an average diameter between about 15 Å and about 50 Å.

38. An electromechanical apparatus produced by the method as recited in claim 28.
